(19) United States
(12) Patent Application Publication
(10) Pub. No.: US 2013/0008712 A1
(43) Pub. Date: Jan. 10, 2013

(54) WIRING TOOL AND WIRING HARNESS

(75) Inventors: Hiroki Kobayashi, Yokkaichi-City (JP); Tatsuya Shimada, Yokkaichi-City (JP); Iwao Wada, Yokkaichi-City (JP); Hideaki Shibata, Yokkaichi-City (JP); Yoshiaki Yamano, Yokkaichi-City (JP); Atsushi Kasamatsu, Yokkaichi-City (JP)

(73) Assignees: AUTONETWORKS TECHNOLOGIES, LTD., Yokkaichi-City (JP); SUMITOMO ELECTRIC INDUSTRIES, LTD., Osaka (JP); SUMITOMO WIRING SYSTEMS, LTD., Yokkaichi-City (JP)

(21) Appl. No.: 13/491,695

(22) Filed: Jun. 8, 2012

(30) Foreign Application Priority Data
Jul. 5, 2011 (JP) 2011-148775

(51) Int. Cl. H05K 13/00; H02G 3/04

(52) U.S. Cl. 174/72 A; 29/745

(57) ABSTRACT

A wiring tool (10) includes a base (1) and a cover (2) each of which is a plate with projections and recesses. The base (1) has partition walls (12A, 12B) standing from a wiring portion (11) to surround protection spaces (90A, 90B) where protected portions (41, 42) are to be arranged. The cover (2) is assembled with the base (1) to cover an area of the base (1) including the wiring portion (11). The cover (2) includes lids (24) that project toward the base (1) and fit into the inner sides of the partition walls (12A, 12B) of the base (1) to close openings formed by the partition walls (12A, 12B). The base (1) and the cover (2) are obtained by vacuum forming a flat resin plate.

### BACKGROUND OF THE INVENTION

1. Field of the Invention

The invention relates to a wiring tool for holding wires in specified shapes and a wiring harness including the same.

2. Description of the Related Art

A wiring harness mounted in a vehicle, such as an automotive vehicle, may include a wiring tool made of resin. The wiring tool is attached to wires and holds the wires held along predetermined paths. For example, a binding member, such as an adhesive tape or a belt, may be used to fix wires of a conventional general wiring harness to a plate-like or bar-like resin member for holding the wires in predetermined shapes.

Japanese Unexamined Patent Publication No. 2010-27242 discloses a wiring harness with a wiring tool that has a plate-like resin base and a plate-like resin cover fixed to the base by heat pressing while sandwiching a wire bundle. A rib stands up from the base and a through hole is formed in the cover for receiving the rib. The wires are placed on the base in a predetermined shape. The cover then is placed on the base to sandwich the wires between the cover and the base. A binding member then fixes the cover to the base to keep the wires in the predetermined shapes.

A wiring harness includes a part that should be covered to prevent contact with other parts for improved durability, electrical insulation and dustproof or waterproof purposes. Such a part is called a protected portion. The protected portion and may include parts of wires or a device connected to the wires, a spliced portion where cores are spliced at an end of a wire bundle or an electronic board connected to the wires.

The protected portion of a conventional wiring harness is protected by a special protection case or a protection tube, such as a heat shrinkable tube or a corrugated tube.

The member and the operation for holding the wires in the predetermined shapes and the member and the operation for covering the protected portion have been separate in the conventional wiring harness. Further, the wiring tool and the protecting tool that covers the protected portion could collide and produce abnormal noise due to vibration, if the protected portion is at intermediate positions of parts of the wires that should be held in the predetermined shapes.

An object of the invention is to hold wires in specified shapes and to provide a simple member and an operation for covering a protected portion of a wiring harness.

### SUMMARY OF THE INVENTION

The invention relates to a wiring tool for holding one or more wires in predetermined specified shapes. The wiring tool comprises a base with a plate that has one or more projections and one or more recesses. The base includes a wiring portion that substantially faces a wiring space where the wires and/or a device connected to the wires are to be arranged. At least one partition wall stands from the wiring portion and includes part of the wiring space where the wires and/or at least one protected portion including the device are to be arranged. The base also has at least one wire fixing portion to which the one or more wires are to be fixed. The wiring tool also includes a cover to be assembled with the base to at least partly cover an area of the base including the wiring portion.

The base preferably is a plate with projections and recesses. The base may include a wiring portion, two first inclined steps, a partition wall and a wire fixing portion. The wiring portion faces a wiring space where the wires or a device connected to the wires may be arranged. The partition wall stands from the wiring portion and defines a part of the wiring space where parts of the wires or a protected portion including the device is to be arranged. The wire fixing portion is a part to which the wires are to be fixed.

The cover may be a plate with one or more projections and one or more recesses and a lid that projects toward the base. The lid is inserted into the inner side of the partition wall of the base to at least partly close an opening formed by the partition wall.

A part of the partition wall in the base may have at least one groove that forms a path for the one or more wires connected to the protected portion.

The base and the cover may be formed integrally and may be connected to at least one bendable, rotatable or pivotable connecting portion. Thus, the number of parts is reduced and an operation of attaching the wiring tool to the wires is simplified.

The base and the covering body may be obtained by applying vacuum forming to a resin member in the form of a substantially flat plate. Generally flat structures obtained by vacuum forming typically can be produced more easily and at lower cost than members obtained by resin injection molding. Accordingly, production man-hours and production cost are reduced by forming the base and the cover by vacuum forming. Note that the base including the rib in the form of a flat plate disclosed in Japanese Unexamined Patent Publication No. 2010-27242 cannot be obtained by vacuum forming a member in the form of a flat plate.

A coating agent may be filled at least partly into the at least one space at the inner side of the partition wall.

The invention also relates to a harness, comprising one or more wires and at least one of the above-described wiring tool.

Wires are sandwiched between the base and the cover of the wiring tool and are fixed by the wire fixing portion provided at a predetermined position on the base. Accordingly, parts fixed by the wire fixing portion are held at a fixed position, and the lengths of parts located at the outer side of the parts fixed by the wire fixing portion are kept constant. Thus, the shapes of the wires are held by the wiring tool so that the ends of the wires reach a connection partner in just proportion.

The protected portion, such as an electronic board connected to the wires or a spliced portion, are covered by the wiring portion and the partition wall of the base and the cover. In this way, the protected portion is protected without being held in contact with other parts.

The wiring tool holds the wires in the predetermined shapes and covers the protected portion. Thus, a wire set including the protected portion is arranged on the wiring portion of the base and parts of the wires are fixed by the wire fixing portion merely by assembling the cover with the base. The shapes of the wires are held and the protected portion is covered by a part of the wiring tool. Accordingly, the wiring tool of invention simplifies a member and an operation for holding the wires in the predetermined shapes and a member and an operation for covering the protected portion.

The partition wall of the base functions as a reinforcement for increasing the rigidity of the plate-like base formed with projections and recesses. Thus, high rigidity can be ensured even if the base is thin for saving space and weight.

The covering body includes the lid that fit into the inner side of the partition wall to close the opening formed by the partition wall. Thus, the inner space of the partition wall is sealed and the protected portion is protected more reliably.

Part of the partition wall in the base may be formed into the wiring groove that forms a path for the wires connected to the protected portion. Thus, the protected portion cannot be lifted up from the inner side of the partition wall due to the resiliency of the wires crossing over the partition wall and an operation of housing the protected portion into the inner side of the partition wall becomes easier.

These and other objects, features and advantages of the invention will become more apparent upon reading the following detailed description of preferred embodiments and accompanying drawings.

### BRIEF DESCRIPTION OF THE DRAWINGS

FIG. 1 is a perspective view of a wiring tool according to an embodiment of the invention.

FIG. 2 is a perspective view of the wiring tool and wires.

FIG. 3 is a perspective view of a wiring harness according to the invention.

FIG. 4 is a section of a part of a first protection space in the wiring harness.

FIG. 5 is a section of a part of a second protection space in the wiring harness.

FIG. 6 is a front view of a wire binding portion of the wiring tool to which the wires are fixed.

FIG. 7 is a perspective view of a connector support and a connector at ends of wires that can be applied to the wiring tool.

### DETAILED DESCRIPTION OF THE PREFERRED EMBODIMENTS

A particular embodiment of the invention is described with reference to the accompanying drawings. The following embodiment is a specific example of the invention and does not limit the scope of the invention.

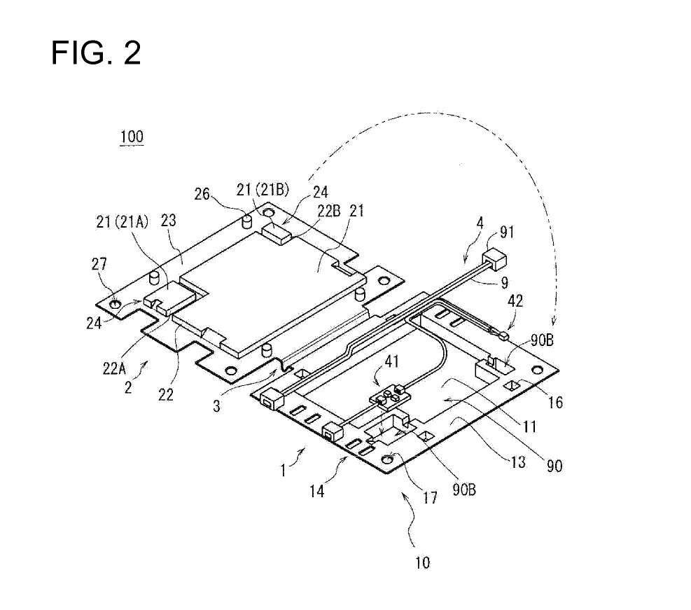

A wiring harness in accordance with the invention is identified by the numeral 100 in FIGS. 2 to 5 and includes a wire set comprising wires 9 and a wiring tool 10 attached to the wires 9. The wiring harness 100 is to be mounted, for example, in a space below a seat, a space under the roof or the trunk in a vehicle and connected to one or more other wires and/or one or more wiring devices. Thus, the wires 9 of the wiring harness 100 are connector-connected wires composed of insulated wires and a connector 91 mounted on ends of the insulated wires.

The plurality of wires 9 of the wiring harness 100 are united by the wiring tool 10 while being held in specified shapes. Thus, the wiring harness 100 can be mounted easily at a predetermined position using a fixing device such as a clamp.

The wiring tool 10 is obtained by applying vacuum forming to a plate-like resin member made, for example, of polypropylene (PP), polyethylene (PE), polyvinylchloride (PVC), polyethylene terephthalate (PET) and/or polyamide (PA).

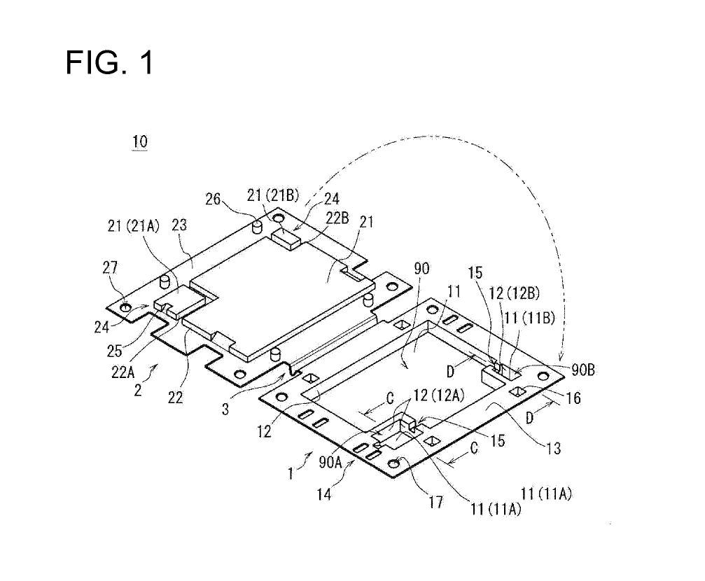

As shown in FIG. 1, the wiring tool 10 includes a base 1, a cover 2 to be placed on the base 1 and a connecting portion 3 unitarily connecting the base 1 and the cover 2. The connecting portion 3 is a resiliently bendable hinge. The cover 2 is assembled with the base 1 while sandwiching intermediate parts of the wires 9 between the base 1 and the cover 2.

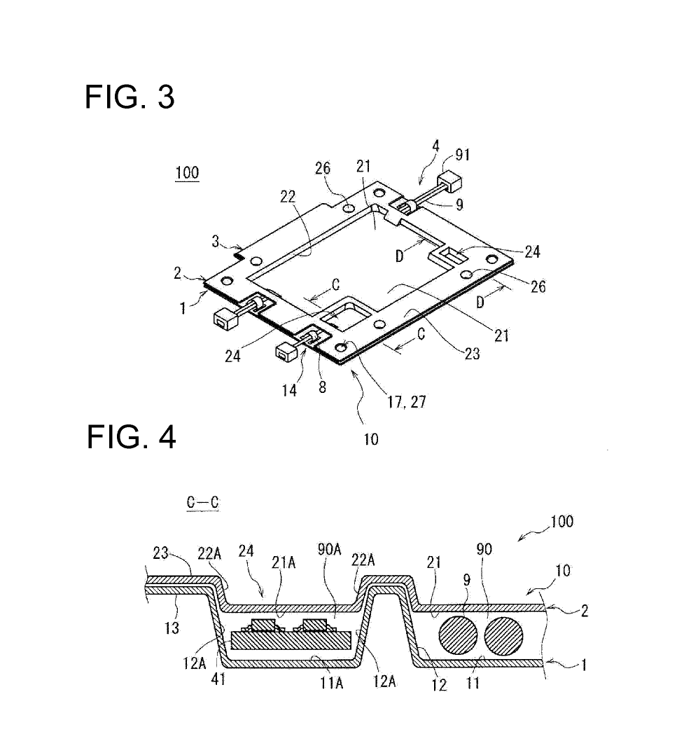

As shown in FIG. 3, the wiring tool 10 is folded or bent at the connecting portion 3 by bending the connecting portion 3 to place the cover 2 on the base 1. The base 1 and the cover 2 are to be fixed while sandwiching the wires 9 therebetween. Thus, the wiring tool 10 holds the wires 9 sandwiched between the base 1 and the cover 2 in specified shapes.

The base 1 of the wiring tool 10 is a resin plate with projections and recesses. As described above, the base 1 is obtained by vacuum forming the resin member substantially in the form of a flat plate. As shown in FIGS. 1 and 2, the base 1 includes a wiring portion 11, a first step 12 and a first frame 13.

The wiring portion 11 of the base 1 is a substantially plate-like part facing a wiring space 90 where the wires 9 are to be arranged. The wiring portion 11 also can be called a bottom or base plate that forms the bottom or base surface of the base 1. The wiring portion 11 shown in FIGS. 1 to 3 is a substantially flat plate, but it may be a plate formed with reinforcing projections. Note that since the base 1 is substantially in the form of a plate with projections and recesses, the reinforcing projections at the side of the wiring space 90 are recesses at a side substantially opposite to the wiring space 90 in the base 1. The reinforcing projections have a lower height than the first step 12.

The first step 12 of the base 1 is formed substantially along the outer edge of the wiring portion 11 and stands from the wiring portion 11 substantially toward the wiring space 90 to form a step. In other words, the outer edge of the wiring portion 11 is formed substantially along the inner edge of the first step 12.

The first step 12 has a substantially constant height in the example shown in FIG. 1, but it may also include at least one part higher than the other parts.

Parts of the first step 12 of the wiring tool 10 at least partly surround protection spaces 90A, 90B (e.g. at four sides). The protection spaces 90A, 90B are areas of the wiring space 90 that parts of the wires or protected portions 41, 42 including one or more devices connected to the wires are arranged.

In an example shown in FIG. 2, the wiring harness 100 specifically includes two protected portions 41, 42. A first protected portion 41 e.g. is an electronic board connected to the wires 9 and a second protected portion 42 e.g. is a spliced portion where cores of wires 9 are spliced by welding. Accordingly, in the example shown in FIGS. 1 to 3, the first step 12 of the wiring tool 10 includes two parts at least partly surrounding the protection spaces 90A, 90B at two positions.

The first step 12 has partition walls 12A, 12B that surround the protection spaces 90A, 90B. Further, the wiring portion 11 has protection chamber bottom plates 11A, 11B inward of the partition walls 12A, 12B and facing the protection spaces 90A, 90B.

The first frame 13 of the base 1 is formed substantially along the outer edge of the first step 12 and forms an outer edge of the base 1. The first frame 13 includes flat parts and recesses or projections in a mixed manner.

Wire binding portions 14 and temporary fastening recesses 16 are formed on the first frame 13. The wire binding portions 14 are parts to which the wires 9 arranged from the wiring portion 11 to the first frame 13 can be fixed.

Clamp holes 17 are formed through parts of the first frame 13 of the base 1 and can receive fixing members, such as clamps, straps, rivets and/or bolts, for mounting the wiring tool 10 on a supporting body, such as a panel of an automotive vehicle. The wiring tool 10 is to be fixed to the supporting body by passing the fixing members (e.g. the clamps) through the respective clamp holes 17 of the base 1 and into mounting holes formed in the supporting body.

The cover 2 of the wiring tool 10 is a substantially plate-shaped resin member that has projections and recesses. More particularly, the cover 2 is configured for covering an area of the base 1 including the wiring portion 11. As described above, the cover 2 and the base 1 in this embodiment are obtained together by vacuum forming a flat plate shaped resin member. As shown in FIGS. 1 and 2, the cover 2 includes a facing wall 21, a second step 22, a second frame 23 and temporary fastening projections 26 formed on parts of the second frame 23. The positions and shapes of the elements of the cover 2 are described in relation to the base 1 for the state where the cover 2 placed on and assembled with the base 1.

The facing wall 21 of the cover 2 is a flat plate that faces the wiring portion 11 of the base 1 across the wiring space 90. However, the facing wall 21 may have reinforcing projections similar to the wiring portion 11 of the base 1.

The second step 22 of the cover 2 is formed along the outer edge of the facing wall 21 and stands from the facing wall 21 to a side opposite the base 1 to form a step. In other words, the outer edge of the facing wall 21 is formed substantially along the inner edge of the second step 22.

In the example shown in FIG. 1, the facing wall 21 and the second step 22 of the cover 2 are recessed toward the base 1 and fit into the inner side of the first step 12 of the base 1 to close an opening formed by the first step 12. Further, in the example shown in FIG. 1, the second step 22 is formed to have a substantially constant height in its entirety. However, the second step 22 may have a part higher than other parts.

The second frame 23 of the cover 2 is formed substantially along the outer edge of the second step 22 and forms an outer part of the cover 2. The second frame portion 23 may include flat parts, recesses and/or projections in a mixed manner. In the example shown in FIG. 1, projections are formed on parts of the second frame 23 and project toward the base 1. Temporary fastening projections 26 are formed on the cover 2.

The second frame 23 of the cover 2 is formed with one or more clamp holes 27. The clamp holes 27 overlap the clamp holes 17 in the first frame 12 of the base 1 when the cover 2 is placed on the base 1. The wiring tool 10 is fixed to the supporting body by the fixing members (e.g. clamps) inserted into the communicating clamp holes 17, 27.

The connecting portion 3 is a substantially plate-like part that can be folded and curved to form a substantially straight groove. The connecting portion 3 is flexible and deformable in directions to open and close the groove formed and is resiliently bendable. The cover 2 is placed on the base 1 at a specified position when the connecting portion 3 is folded along the groove.

The temporary fastening recesses 16 are formed on parts of the first frame 13 of the base 1. In the example shown in FIG. 1, four temporary fastening recesses 16 are formed near the wire binding portions 14 of the first frame 13 and near the connecting portion 3. The temporary fastening recesses 16 are depressions that open toward the cover 2.

On the other hand, the temporary fastening projections 26 to be fit into the temporary fastening recesses 16 of the base 1 are formed on parts of the second frame 23 of the cover 2. In the example shown in FIG. 1, the four temporary fastening projections 26 are formed at positions respectively facing the four temporary fastening recesses 16.

The temporary fastening recesses 16 formed on the base 1 and the temporary fastening projections 26 formed on the cover 2 form a temporary fastening mechanism for fastening the cover 2 to the base 1.

The side surfaces of the temporary fastening projections 26 are shaped to contact the inner wall surfaces of the temporary fastening recesses 16 while being slightly compressed or deformed. In this way, frictional resistance between the side surfaces of the temporary fastening projections 26 and the inner surfaces of the temporary fastening recesses 16 fasten the cover 2 to the base 1 while covering the wiring portion 11 of the base 1 when the temporary fastening projections 26 are pushed into the temporary fastening recesses 16.

As described above, the temporary fastening recesses 16 and the temporary fastening projections 26 form the temporary fastening mechanism for fastening the cover 2 to the base 1 while covering the wiring portion 11 by a projection/recess fitting structure.

The temporary fastening recesses 16 are on the base 1 and the temporary fastening projections 26 are on the cover portion 2 in the example shown in FIG. 1. However, a reverse or partially reverse configuration is also possible. That is, the temporary fastening recesses 16 may be on the cover 2 and the temporary fastening projections 26 may be on the base 1. Further, the temporary fastening recesses 16 and the temporary fastening projections 26 may be provided in a mixed manner on each of the base 1 and the cover 2.

As shown in FIGS. 2 and 3, the wiring harness 100 includes the wires 9 and the wiring tool 10 for holding the wires 9 in the specified shapes.

Intermediate parts of the wires 9 are arranged on the wiring portion 11 of the base 1. Further, the connector 91 at the ends of the wires 9 is outside the base 1 and the wires 9 mounted on the connector 91 are arranged from the wiring portion 11 of the base 1 to the outside of the first frame 13 via the first step 12 and the wire binding portion 14 on the first frame 13. The wires 9 are fixed to the wire binding portion 14 e.g. by a binding belt.

As shown in FIG. 3, the base 1 and the cover 2 are fixed in an assembled state while sandwiching the intermediate parts of the wires 9 arranged on the wiring portion 11 between the wiring portion 11 and the facing wall 21. In this embodiment, parts of the temporary fastening recesses 16 and the temporary fastening projections 26 held in contact with each other particularly are glued or welded (particularly by a device for spot heating such as ultrasonic welding). Thus, the cover 2 is fixed to the base 1 while sandwiching the intermediate parts of the wires 9 between the base 1 and the cover 2.

Bottom surfaces of the temporary fastening recesses 16 and top surfaces of the temporary fastening projections 26 may come into contact when the temporary fastening projections 26 are inserted into the temporary fastening recesses 16. However, welds are formed at parts where the bottom surfaces of the temporary fastening recesses 16 and the top surfaces of the temporary fastening projections 26 are in contact.

FIG. 6 is a front view of the wire binding portion 14 to which the wires 9 are fixed. Note that, in FIG. 6, the cross section of the wires 9 is shown with end portions of the wires 9 omitted. As shown in FIG. 6, the wire binding portion 14 comprises a wire insertion portion 141 on the first frame 13 and two belt insertion holes 142 at opposite sides of the wire insertion portion 141. The wire insertion portion 141 is a part of the first frame 13 where the wires 9 are passed. The belt insertion holes 142 are adjacent to the wire insertion portion 141. The belt insertion holes 142 can receive a belt portion 81 of a binding belt 8 for binding the wires 9 to the wire insertion portion 141 of the wire binding portion 14. Note that the binding belt 8 merely is an example of a binding member. The through hole of the belt insertion portion 142 is formed, for example, by performing Thompson machining on the flat resin plate before being vacuum formed.

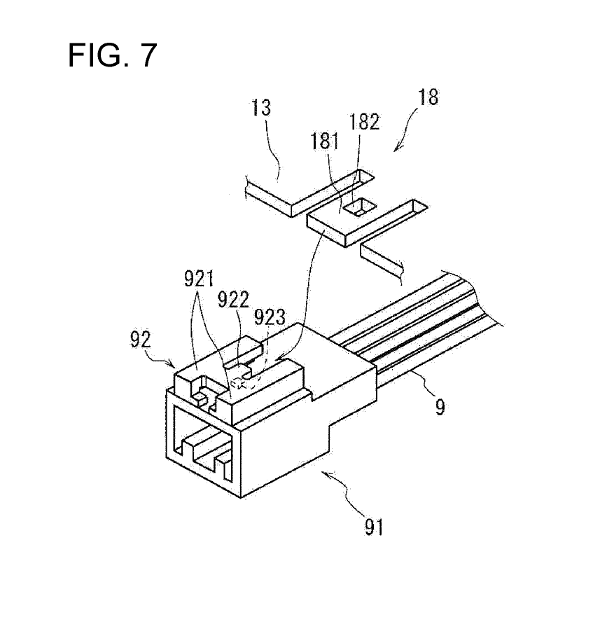

A connector support 18, as shown in FIG. 7, is another example of a wire fixing portion that can be applied to the wiring tool 10. The connector support 18 is formed at a part of the first frame portion 13 of the base 1 to which the connector 91 at the ends of the wires 9 is fixed. As shown in FIG. 7, the connector 91 at the ends of the wires 9 is formed with a coupling 92 to be coupled to another member such as a clamp. The coupling 92 includes two straight parallel guide rails 921 that are spaced apart for receiving a part of a mating member. A bridge 922 bridges between the guide rails 921 and defines a beam spaced from the outer surface of the connector 91. A projection 923 is formed on a surface of the bridge 922 facing the bottom surface of the main body of the connector 91 and projects toward a main body of the connector 91. The connector 91 shown in FIG. 7 is used widely in wiring harnesses to be mounted in automotive vehicles.

As shown in FIG. 7, the connector support 18 includes a fitting piece 181 to be inserted into the clearance between the guide rails 921 in the coupling 92 of the connector 91. The fitting piece 181 is formed between two cuts formed in an edge of the first frame portion 13. Further, the fitting piece 181 has a fitting recess or hole 182 for receiving the projection 923 of the coupling 92 when the fitting piece 181 is inserted into the clearance between the guide rails 921.

The fitting piece 181 is inserted into the clearance between the guide rails 921 in the coupling 92 to fix the connector 91 to the connector support 18. Thus, the connector support 18 engages the coupling 92 on the connector 91 mounted on the ends of the wires 9 to support the connector 91.

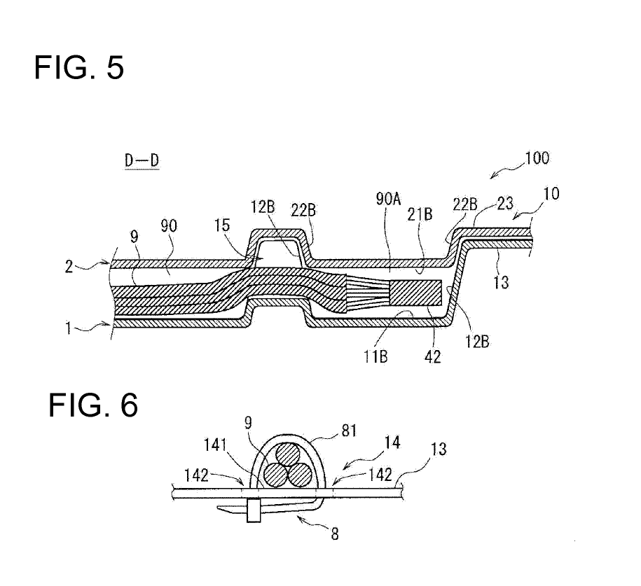

The of the wiring tool 10 for housing the protected portions 41, 42 in the protection spaces 90A, 90B are described in detail with reference to FIGS. 4 and 5. Specifically, the base 1 has the protection chamber bottom plates 11A, 11B that face the protection spaces 90A, 90B in the wiring space 90 where the wires 9 and the device connected to the wires 9 are arranged. Further, as shown in FIGS. 2, 4 and 5, the partition wall portions 12A, 12B of the base 1 stand from the protection chamber bottom plates 11A, 11B and surround the protection spaces 90A, 90B where the protected portions 41, 42 are to be arranged.

Parts of the second step 22 of the cover 2 surround parts of the facing wall portion 21 substantially facing the protection chamber bottom plates 11A, 11B of the base 1. The parts of the facing wall 21 that face the protection chamber bottom plates 11A, 11B of the base 1 are referred to as protection chamber ceilings 21A, 21B. Further, parts of the second step 22 of the cover 2 formed substantially along the outer edges of the protection chamber ceilings 21A, 21B are referred to as ceiling supports 22A, 22B.

The protection chamber ceilings 21A, 21B and the ceiling supports 22A, 22B of the cover 2 form lids 24 that project toward the base 1. The lids 24 are to be fit into the inner sides of the partition walls 12A, 12B of the base 1 to close openings formed by the partition walls 12A, 12B. As shown in FIGS. 4 and 5, the ceiling supports 22A, 22B form steps extending along the inner side surfaces of the partition walls 12A, 12B. In this way, the openings formed by the partition walls 12A, 12B are closed by the lids 24 with high sealing ability.

The lids 24 of the cover 2 may also include wiring grooves 25 that form paths for the wires 9 connected to the protected portions 41, 42, as shown in FIG. 1 and in a manner similar to the partition walls 12A, 12B.

A coating agent, such as resin or rubber, may be filled in the protection spaces 90A, 90B at the inner sides of the partition wall portions 12A, 12B where the protected portions 41, 42 are arranged to improve dustproof and fluid- or waterproof effects for the protected portions 41, 42.

The partition walls 12A and 12B have wiring groove 15 that form paths for the wires 9 connected to the first and second protected portions 41 and 42 respectively, as shown in FIGS. 1 and 5. More particularly, the partition wall 12A also has two wiring grooves 15 and the partition wall 12B is formed with one wiring groove 15.

Parts of the wires 9 other than the protected portions 41, 42 are housed in parts of the wiring space 90 outside the protection spaces 90A, 90B, as shown in FIG. 4.

The wires 9 of the wiring harness 100 are sandwiched between the base 1 and the cover 2 of the wiring tool 10. Further, the wires 9 arranged from the wiring portion 11 on the inner side to the first frame 13 of the base 1 are fixed by the wire binding portions 14 and the connector supports 18 provided at specified positions on the first frame 13. Accordingly, the lengths of parts of the wires 9 located at the outer sides of the wire binding portions 14 and the connector supports 18 are kept constant. That is, the shapes of the wires 9 are held by the wiring tool 10 so that the ends of the wires 9 reach a connection partner in just proportion. Further, the wires 9 are protected by the base 1 and the cover 2.

The protected portions 41, 42 such as the electronic board connected to the wires 9 and the spliced portion that is part of the wires 9 are covered by the protection chamber bottom plates 11A, 11B and the partition walls 12A, 12B of the base 1 and the protection chamber ceilings 21A, 21B of the cover 2. In this way, the protected portions 41, 42 are protected without being held in contact with other parts.

The wiring tool 10 holds the wires 9 in the specified shapes and covers the protected portions 41, 42. That is, the shapes of the wires 9 are held and the protected portions 41, 42 are covered by parts of the wiring tool 10 merely by arranging the wire set including the protected portions 41, 42 on the wiring portion 11 of the base 1, fixing parts of the wires 9 with the wire binding portions 14 and the connector supports 18, and assembling the cover 2 with the base 1. Accordingly, the wiring tool 10 simplifies the member and operation for holding the wires 9 in the specified shapes and simplifies the member and operation for covering the protected portions 41, 42.

The partition walls 12A, 12B of the base 1 function as reinforcements for increasing the rigidity of the base 1. Thus, high rigidity can be ensured even if the base portion 1 is made relatively thin to save space and weight.

The lids 24 project on the cover 2 and can fit into the inner sides of the partition walls 12A, 12B to close the openings formed by the partition walls 12A, 12B. Thus, sealing of the protection spaces 90A, 90B at the inner sides of the partition walls 12A, 12B is improved and the protected portions 41, 42 are protected more reliably.

A coating agent such as resin or rubber may be filled at least partly in the protection spaces 90A, 90B inward of the partition walls 12A, 12B to improve dustproof and/or fluid- or waterproof effects for the protected portions 41, 42.

The wiring grooves 15 are formed in the partition walls 12A, 12B of the base 1. Thus, the protected portions 41, 42 are not lifted from the inner sides of the partition walls 12A, 12B by the resiliency of the wires 9 crossing over the partition walls 12A, 12B. Thus, the protected portions 41, 42 are retained more easily at the inner sides of the partition walls 12A, 12B.

The base 1 and the cover 2 may be formed by different members. However, the base 1 and the cover 2 preferably are connected unitarily by the bendable connecting portion 3. Thus, the number of parts is reduced and the operation of attaching the wiring tool 10 to the wires 9 is simplified further.

The base 1 and the cover 2 may be obtained by resin injection molding. However, the wiring tool 10 is a plate with projections and recesses only in a vertical direction. This shape is obtained easily by vacuum forming a resin plate. Members obtained by applying vacuum forming top a flat plate can be produced more easily and at lower cost than members obtained by resin injection molding. Therefore, the wiring tool 10 preferably is obtained by applying vacuum forming to a flat plate. Accordingly, production man-hours and production cost are reduced.

What is claimed is:

1. A wiring tool (10) for holding at least one wire (9) in specified shapes, comprising:
a base (1) defining a plate with at least one projections and a least one recess and including a wiring portion (11) that faces a wiring space (90) where the wire (9) and a device (91) connected to the wire (9) are to be arranged, at least one partition wall (12A; 12B) standing from the wiring portion (11) and including a partial space (90A; 90B) of the wiring space (90) where parts of the wire (9) and at least one protected portion (41; 42) including the device is to be arranged, and at least one wire fixing portion (14; 18) to which the wire (9) is be fixed; and
a cover (2) to be assembled with the base (1) to at least partly cover an area of the base (1) including the wiring portion (11).

2. The wiring tool of claim 1, wherein the cover (2) is a plate with at least one projections and at least one recess, a lid (24) projecting from the cover (2) toward the base (1) and inserted into the inner side of the partition wall (12A; 12B) of the base (1) to at least partly close an opening formed by the partition wall portion (12A; 12B).

3. The wiring tool of claim 2, further comprising at least one groove (15; 25) formed in a part of the partition wall (12A; 12B) in the base (1) to define a path for the wire (9) connected to the protected portion (41; 42).

4. The wiring tool of claim 3, wherein the base (1) and the cover (2) are joined integrally by at least one bendable or rotatable connecting portion (3).

5. The wiring tool of claim 1, wherein the base (1) and the cover (2) are obtained by vacuum forming a substantially flat resin plate.

6. The wiring tool of claim 1, further comprising a coating agent filled at least partly into the at least one space (90A; 90B) at the inner side of the partition wall (12A; 12B).

7. A wiring harness, comprising: at least one wire (9); and the wiring tool (10) of claim 1 for holding the wire (9) in a specified shape.
